(19) United States
(12) Patent Application Publication
(10) Pub. No.: US 2026/0033261 A1
(43) Pub. Date: Jan. 29, 2026

(54) ETCHING METHOD AND ETCHING APPARATUS

(71) Applicants: Tokyo Electron Limited, Tokyo (JP); National University Corporation Tokai National Higher Education and Research System, Nagoya-shi (JP)

(72) Inventors: Tadashi MITSUNARI, Nirasaki-shi (JP); Yuki IIJIMA, Kurokawa-gun (JP); Wataru TAKAYAMA, Kurokawa-gun (JP); Masaru HORI, Nagoya-shi (JP); Makoto SEKINE, Nagoya-shi (JP)

(21) Appl. No.: 19/347,868

(22) Filed: Oct. 2, 2025

Related U.S. Application Data
(63) Continuation of application No. PCT/JP2024/012306, filed on Mar. 27, 2024.

(30) Foreign Application Priority Data
Apr. 6, 2023 (JP) 2023-062391

(51) Int. Cl. H01L 21/3213; H01J 37/32

(52) U.S. Cl. CPC H01L 21/32137; H01J 37/32449; H01L 21/32139; H01J 2237/3341; H01J 2237/3346

(57) ABSTRACT

An etching method includes: a) preparing, within a chamber, a substrate including a mask film containing ruthenium and having a predetermined pattern formed in the mask film, and a silicon-containing film provided under the mask film; b) supplying a process gas including a hydrocarbon-containing gas and a fluorine-containing gas into the chamber; and c) etching the silicon-containing film through the mask film using plasma generated from the process gas supplied into the chamber.

### CROSS-REFERENCE TO RELATED APPLICATION

The application is a Bypass Continuation application of PCT International Application No. PCT/JP2024/012306, filed on Mar. 27, 2024 and designating the United States, the international application being based upon and claiming the benefit of priority from Japanese Patent Application No. 2023-062391, filed on Apr. 6, 2023, the entire content of which is incorporated herein by reference.

### TECHNICAL FIELD

Various aspects and embodiments of the present disclosure relate to an etching method and an etching apparatus.

### BACKGROUND

Patent Document 1 below discloses a method of etching a substrate, including: providing a target etch layer on the substrate; providing a patterned layer covering the target etch layer; providing a hard mask layer including ruthenium between the target etch layer and the patterned layer, etching a pattern of the patterned layer into the hard mask layer to form a patterned hard mask layer; and etching the target etch layer while utilizing the patterned hard mask layer as a masking layer for the etching of the target etch layer.

### PRIOR ART DOCUMENTS

### Patent Documents

Patent Document 1: Japanese Patent Laid-open Publication No. 2021-534575

### SUMMARY

According to one embodiment of the present disclosure, there is provided an etching method, including: a) preparing, within a chamber, a substrate including a mask film containing ruthenium and having a predetermined pattern formed in the mask film, and a silicon-containing film provided under the mask film; b) supplying a process gas including a hydrocarbon-containing gas and a fluorine-containing gas into the chamber; and c) etching the silicon-containing film through the mask film using plasma generated from the process gas supplied into the chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating an example of a plasma processing system.

FIG. 2 is a flowchart illustrating an example of an etching method.

FIG. 3A is a diagram illustrating an example of a relationship between the content of ruthenium in a mask film and an etch rate under processing conditions of a comparative example.

FIG. 3B is a diagram illustrating an example of a relationship between the content of ruthenium in a mask film and an etch rate under processing conditions of the present embodiment.

FIG. 4A is a schematic diagram illustrating an example of a cross-section of a substrate before etching is performed.

FIG. 4B is a schematic diagram illustrating an example of a cross-section of a substrate when etching is performed under processing conditions of the comparative example.

FIG. 4C is a schematic diagram illustrating an example of a cross-section of a substrate when etching is performed under processing conditions of the present embodiment.

FIG. 5 is a diagram illustrating an example of a Raman shift of the uppermost surface of a mask film.

FIG. 6 is a diagram illustrating an example of a relationship between an etching processing time and an etch rate using a process gas including CF₄ gas and CH₄ gas for each of amorphous carbon and ruthenium.

FIG. 7 is a diagram illustrating an example of a relationship between a set temperature of a base and an etch rate.

FIG. 8 is a diagram illustrating an example of a relationship between an addition ratio of CH₄ gas and a change in thickness of a mask film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of an etching method and an etching apparatus will be described in detail with reference to the drawings. The disclosed etching method and etching apparatus are not limited by the embodiments below.

With the miniaturization of a semiconductor process and the high density of a semiconductor device in recent years, an increase in the aspect ratio of a trench or a hole formed by etching has been required. In order to increase the aspect ratio of the trench or the hole, it is necessary to improve the selectivity of a mask film with respect to an etching target film. In Patent Document 1 described above, etching is performed using the hard mask film containing ruthenium, but further improvement in the selectivity of the mask film with respect to the etching target film is required.

Therefore, the present disclosure provides a technique capable of improving the selectivity of a mask film with respect to an etching target film.

### [Configuration of Plasma Processing System]

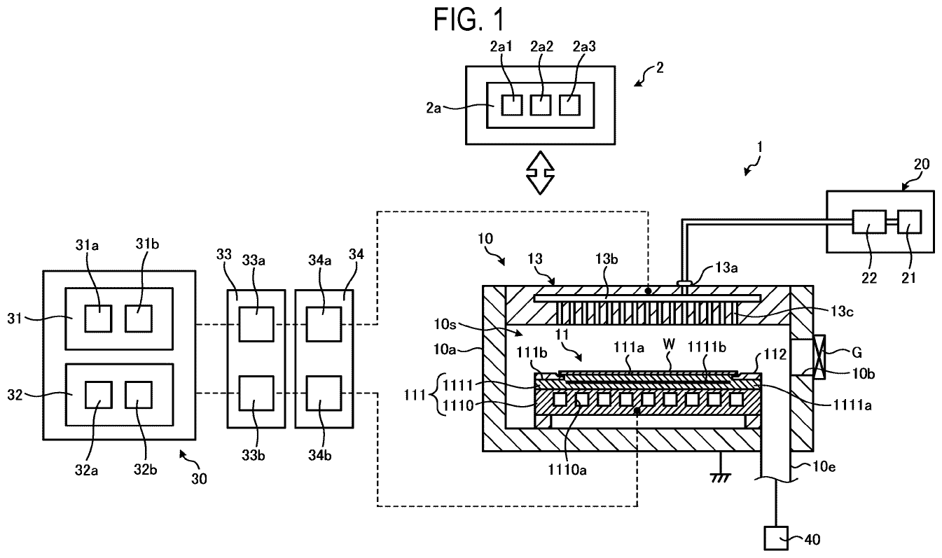

Hereinbelow, a configuration example of a plasma processing system will be described. FIG. 1 is a schematic diagram illustrating an example of a plasma processing system. The plasma processing system includes a capacitively coupled plasma processing apparatus 1 and a controller 2. The plasma processing apparatus 1 is an example of an etching apparatus. The capacitively coupled plasma processing apparatus 1 includes a plasma processing chamber 10, a gas supply 20, a power supply 30, a waveform generator 33, an impedance matching circuit 34, and an exhaust system 40. The plasma processing apparatus 1 further includes a substrate support 11 and a gas introducer. The gas introducer is configured to introduce at least one process gas into the plasma processing chamber 10. The gas introducer includes a shower head 13. The substrate support 11 is disposed inside the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11.

The plasma processing chamber 10 has at least one gas supply port 13a for supplying at least one process gas to the plasma processing space 10s and at least one gas discharge port 10e for discharging gas from the plasma processing space 10s. The plasma processing chamber 10 is made of a conductor such as aluminum and is grounded. The shower head 13 and the substrate support 11 are electrically insulated from a housing of the plasma processing chamber 10. An opening 10b for loading a substrate W into the plasma processing chamber 10 and unloading the substrate W from the plasma processing chamber 10 is formed in the side wall 10a of the plasma processing chamber 10. The opening 10b is opened and closed by a gate valve G.

The substrate support 11 includes a main body 111 and a ring assembly 112. The main body 111 has a central region 111a for supporting the substrate W and an annular region 111b for supporting the ring assembly 112. A wafer is an example of the substrate W. The annular region 111b of the main body 111 surrounds the central region 111a of the main body 111 when viewed in plan. The substrate W is disposed on the central region 111a of the main body 111, and the ring assembly 112 is disposed on the annular region 111b of the main body 111 so as to surround the substrate W disposed on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductive member. The conductive member of the base 1110 can serve as a lower electrode. The electrostatic chuck 1111 is disposed on the base 1110. The electrostatic chuck 1111 includes a ceramic member 1111a and an electrostatic electrode 1111b disposed within the ceramic member 1111a. The ceramic member 1111a has the central region 111a. In one embodiment, the ceramic member 1111a also has the annular region 111b. Another member surrounding the electrostatic chuck 1111, such as an annular electrostatic chuck (not shown) or an annular insulating member (not shown), may have the annular region 111b. In this case, the ring assembly 112 may be disposed on the annular electrostatic chuck or the annular insulating member or may be disposed on both the electrostatic chuck 1111 and the annular insulating member. In addition, at least one radio frequency (RF)/direct current (DC) electrode, which is coupled to at least one of an RF power supply 31 or a DC power supply 32 described later, may be disposed within the ceramic member 1111a. In this case, the at least one RF/DC electrode functions as a lower electrode. When at least one of a bias RF signal or a DC signal described later is supplied to the at least one RF/DC electrode, the RF/DC electrode is also called a bias electrode. In addition, the conductive member of the base 1110 and the at least one RF/DC electrode may function as a plurality of lower electrodes. Furthermore, the electrostatic electrode 1111b may function as the lower electrode. Therefore, the substrate support 11 includes at least one lower electrode.

The ring assembly 112 includes one or a plurality of annular members. In one embodiment, the one or the plurality of annular members includes one or a plurality of edge rings and at least one cover ring. The edge ring is made of a conductive material or an insulating material, and the cover ring is made of an insulating material.

The substrate support 11 may include a temperature adjustment module configured to adjust at least one of the electrostatic chuck 1111, the ring assembly 112, or the substrate to a target temperature. The temperature adjustment module may include a heater, a heat transfer medium, a flow passage 1110a, or a combination thereof. A heat transfer fluid such as brine or gas flows through the flow passage 1110a. In one embodiment, the flow passage 1110a is formed within the base 1110, and one or a plurality of heaters is disposed within the ceramic member 1111a of the electrostatic chuck 1111. When the substrate W is processed at a low temperature (below room temperature), the heater is not disposed within the ceramic member 1111a, and the temperature control of the substrate W may be performed by the heat transfer medium. The substrate support 11 may include a heat transfer medium supply configured to supply a heat transfer medium including a heat transfer gas to a gap between a rear surface of the substrate W and the central region 111a.

A through hole (not shown) is formed in the electrostatic chuck 1111 below the central region 111a, and a lift pin (not shown) is inserted into this through hole. The lift pin is raised and lowered by a lift mechanism, which is not shown. By raising and lowering the lift pin, the substrate W placed on the central region 111a can be raised and lowered. For example, after the gate valve G is opened, the substrate W is loaded into the plasma processing chamber 10 by a transfer robot (not shown) through the opening 10b and placed on the lift pin, a tip end of which protrudes from an upper surface of the electrostatic chuck 1111. When the lift pin is lowered, the substrate W is placed on the electrostatic chuck 1111, the gate valve G is closed, and a processing is performed on the substrate W inside the plasma processing chamber 10. After the processing, the lift pin is raised, and the substrate W is lifted from the upper surface of the electrostatic chuck 1111. After the gate valve G is opened, the substrate W is unloaded from the plasma processing chamber 10 by the transfer robot (not shown) through the opening 10b.

The shower head 13 is configured to introduce at least one process gas from the gas supply 20 into the plasma processing space 10s. The shower head 13 includes at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the plurality of gas introduction ports 13c. The shower head 13 further includes at least one upper electrode (not shown). The gas introducer may include, in addition to the shower head 13, one or a plurality of side gas injectors (SGIs) installed in one or a plurality of openings (not shown) formed in the side wall 10a.

The gas supply 20 may include at least one gas source 21 and at least one flow rate controller 22. In one embodiment, the gas supply 20 is configured to supply at least one process gas to the shower head 13 from each corresponding gas source 21 through each corresponding flow rate controller 22. Each flow rate controller 22 may include, for example, a mass flow controller or a pressure-controlled flow rate controller. In addition, the gas supply 20 may include one or more flow rate modulation devices that modulate or pulse the flow rate of the at least one process gas.

The power supply 30 includes the RF power supply 31 coupled to the plasma processing chamber 10 via at least one impedance matching circuit 34. The RF power supply 31 is configured to supply at least one RF signal (RF power) to at least one lower electrode, at least one upper electrode, or both of the at least one lower electrode and the at least one upper electrode. Thereby, plasma is formed from the at least one process gas supplied to the plasma processing space 10s. Therefore, the RF power supply 31 may function as at least part of a plasma generator configured to generate plasma from one or more process gases in the plasma processing chamber 10. Additionally, by supplying a bias RF signal to the at least one lower electrode, a bias potential can be generated on the substrate W, thereby attracting ion components in the formed plasma to the substrate W.

In one embodiment, the RF power supply 31 includes a first RF generator 31a and a second RF generator 31b. The first RF generator 31a is configured to generate a source RF signal (source RF power) for plasma generation by being coupled to the at least one lower electrode, the at least one upper electrode, or both of the at least one lower electrode and the at least one upper electrode through at least one first impedance matching circuit 34a. In one embodiment, the source RF signal has a frequency in a range of 10 MHz to 150 MHz. In one embodiment, the first RF generator 31a may be configured to generate a plurality of source RF signals having different frequencies. The generated one or plural source RF signals are supplied to the at least one lower electrode, the at least one upper electrode, or both of the at least one lower electrode and the at least one upper electrode.

The second RF generator 31b is configured to generate a bias RF signal (bias RF power) by being coupled to the at least one lower electrode through at least one second impedance matching circuit 34b. The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or plural bias RF signals are supplied to the at least one lower electrode. In various embodiments, at least one of the source RF signal or the bias RF signal may be pulsed.

In addition, the power supply 30 may include the DC power supply 32 coupled to the plasma processing chamber 10. The DC power supply 32 includes a first DC generator 32a and a second DC generator 32b. In one embodiment, the first DC generator 32a is configured to generate a first DC signal by being connected to the at least one lower electrode. The generated first bias DC signal is applied to the at least one lower electrode. In one embodiment, the second DC generator 32b is configured to generate a second DC signal by being connected to the at least one upper electrode. The generated second DC signal is applied to the at least one upper electrode.

In various embodiments, at least one of the first DC signal or the second DC signal may be pulsed. In this case, a sequence of voltage pulses is applied to the at least one lower electrode, the at least one upper electrode or both of the at least one lower electrode and the at least one upper electrode. The voltage pulses may have rectangular, trapezoidal, or triangular pulse waveforms, or combinations thereof. In one embodiment, a second waveform generator 33b of the waveform generator 33 for generating the sequence of the voltage pulses from the DC signal is connected between the first DC generator 32a and the at least one lower electrode. Accordingly, the first DC generator 32a and the second waveform generator 33b constitute a voltage pulse generator. When the second DC generator 32b and a first waveform generator 33a of the waveform generator 33 constitute the voltage pulse generator, the voltage pulse generator is connected to the at least one upper electrode. The voltage pulses may have positive polarity or negative polarity. Further, the sequence of the voltage pulses may include one or plural positive voltage pulses and one or plural negative voltage pulses within one cycle. The first and second DC generators 32a and 32b may be provided in addition to the RF power supply 31, or the first DC generator 32a may be provided instead of the second RF generator 31b.

The exhaust system 40 can be connected, for example, to a gas discharge port 10e provided at the bottom of the plasma processing chamber 10. The exhaust system 40 may include a pressure regulating valve and a vacuum pump. Pressure inside the plasma processing space 10s is regulated by the pressure regulating valve. The vacuum pump may include a turbomolecular pump, a dry pump, or a combination thereof.

The controller 2 processes a computer-executable instruction that causes the plasma processing apparatus 1 to execute various processes described in the present disclosure. The controller 2 may be configured to control each element of the plasma processing apparatus 1 to execute various processes described herein. In one embodiment, a part or all of the controller 2 may be included in the plasma processing apparatus 1. The controller 2 may include a processor 2a1, a storage portion 2a2, and a communication interface 2a3. The controller 2 is achieved by, for example, a computer 2a. The processor 2al may be configured to perform various control operations by reading a program from the storage portion 2a2 and executing the read program. This program may be stored in the storage portion 2a2 in advance or may be acquired from a medium when necessary. The acquired program is stored in the storage portion 2a2 and is read from the storage portion 2a2 and executed by the processor 2al. The medium may be various non-transitory storage media readable by the computer 2a or may be a communication line connected to the communication interface 2a3. The processor 2al may be a central processing unit (CPU). The storage portion 2a2 may include a random access memory (RAM), a read only memory (ROM), a hard disk drive (HDD), a solid state drive (SSD), or a combination thereof. The communication interface 2a3 may communicate with the plasma processing apparatus 1 via the communication line such as a local area network (LAN).

### [Etching Method]

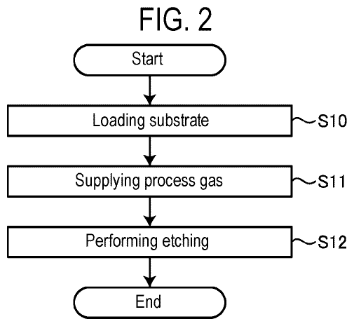

FIG. 2 is a flowchart illustrating an example of an etching method. The etching method illustrated in FIG. 2 is implemented by the controller 2 controlling each part of the plasma processing apparatus 1.

First, the substrate W as an etching target is loaded into the plasma processing chamber 10 (S10). Step S10 is an example of Process a). In the present embodiment, the substrate W as the etching target includes a mask film on which a predetermined pattern is formed and a silicon-containing film provided under the mask film. In the present embodiment, the mask film contains ruthenium. The silicon-containing film is a film containing silicon. The film containing silicon is, for example, a silicon oxide film, a silicon nitride film, or a multilayer film in which the silicon oxide film and the silicon nitride film are alternately stacked. The silicon-containing film is an example of an etching target film.

In step S10, for example, the gate valve G is opened under control of the controller 2, and the substrate W is loaded into the plasma processing chamber 10 via the opening 10b by the transfer robot (not shown). The substrate is then placed on the lift pin, the tip end of which protrudes from the upper surface of the electrostatic chuck 1111. Next, the controller 2 controls a driving portion of the lift pin, so that the lift pin is lowered, and the substrate W is placed on the electrostatic chuck 1111. Then, the gate valve G is closed under control of the controller 2, and the substrate W is prepared in the chamber.

Thereafter, a process gas is supplied into the plasma processing chamber 10 (step S11). Step S11 is an example of Process b). In step S11, the process gas supplied from the gas supply 20 is supplied into the plasma processing chamber 10 via the shower head 13. The process gas includes a hydrocarbon-containing gas and a fluorine-containing gas. In the present embodiment, the hydrocarbon gas is, for example, CH₄ gas, and the fluorine-containing gas is, for example, CF₄ gas. In addition, as the hydrocarbon gas, for example, C₂H₂ gas or C₃H₆ gas may be used. As the fluorine-containing gas, for example, C₄F₆ gas may be used.

Here, non-patent document 1 shows the types of active species generated when another CₓH_{y} gas is introduced into plasma.

### Non-Patent Document 1

R. Kleber et al. “Influence of ion energy and flux composition on the properties of plasma-deposited amorphous carbon and amorphous hydrogenated carbon films” Diamond and Related Materials Volume 2, Issues 2-4, 31 Mar. 1993, Pages 246-250

In general, when gas molecules are introduced into plasma, the molecules undergo reactions such as dissociation and polymerization, due to collision with electrons or active particles in the plasma, and change into other molecules or atoms. In the present embodiment, CH₄ gas is shown as an example of the hydrocarbon gas. However, when CH₄ gas is introduced into the plasma, various polymerization species such as CHₓ, C₂H_{y}, and C₃H_{z} are generated by polymerization, and it is considered that these polymerization species also contribute to a surface layer reaction. Even when a gas, such as C₂H₂ gas or C₃H₆ gas, other than CH₄, is introduced, dissociation and polymerization similarly occur, and a large number of CₓH_{y} gases is generated. Thereby, it is considered that the method proposed in the present embodiment is applicable even when the hydrocarbon gas other than CH₄ gas is used.

Next, an etching process is performed on the substrate W (S12). Step S12 is an example of Process c). In step S12, by supplying RF power into the plasma processing chamber 10, the plasma is generated from the process gas in the plasma processing chamber 10, and the etching process is performed on the substrate W by ions or active species included in the plasma. Then, the etching method in the present embodiment is ended.

Main processing conditions in step S12 are as follows.
Frequency of RF power (for plasma generation): 40 MHz to 100 MHz (e.g., 40 MHz)
Frequency of RF power (for bias): 400 kHz to 27 MHz (e.g., 3.2 MHz)
RF power (for plasma generation): 2 kW to 10 KW (e.g., 4 kW)
RF power (for bias): 2 kW to 10 KW (e.g., 7 kW)
Process gas and flow rate ratio: CH₄ gas: CF₄ gas=1:99 to 50:50 (e.g., 20:80)
Pressure inside plasma processing chamber 10: 10 mTorr to 80 mTorr (1.3 Pa to 10.7 Pa) (e.g., 20 mTorr (2.7 Pa))
Temperature of substrate W: −60 degrees C. to 0 degrees C. (e.g., −30 degrees C.)

### [Process Gas and Content of Ruthenium in Mask Film]

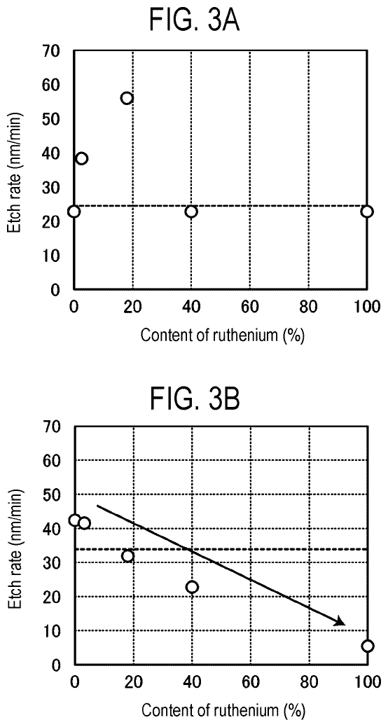

FIG. 3A is a diagram illustrating an example of a relationship between the content of ruthenium in a mask film and an etch rate under processing conditions of a comparative example. In the comparative example, the process gas contains CF₄ gas but does not contain CH₄ gas. The other processing conditions are the same as the processing conditions of the present embodiment described above. In FIG. 3A, for comparison, the etch rate of the mask film in which only amorphous carbon is used is indicated by a broken line.

As illustrated in FIG. 3A, under the processing conditions of the comparative example, even if the content of ruthenium in the mask film is varied, a minimum value of the etch rate of the mask film is almost the same as the etch rate of the mask film in which only amorphous carbon is used.

On the other hand, under processing conditions of the present embodiment, as illustrated in FIG. 3B, as the content of ruthenium in the mask film increases, the etch rate of the mask film decreases. In the example of FIG. 3B, when the content of ruthenium in the mask film is in a range of 20% or more, the etch rate of the mask film is lower than the etch rate of the amorphous carbon. That is, when the content of ruthenium is 20% or more, the plasma resistance of the mask film can be improved compared to the mask film in which only amorphous carbon is used.

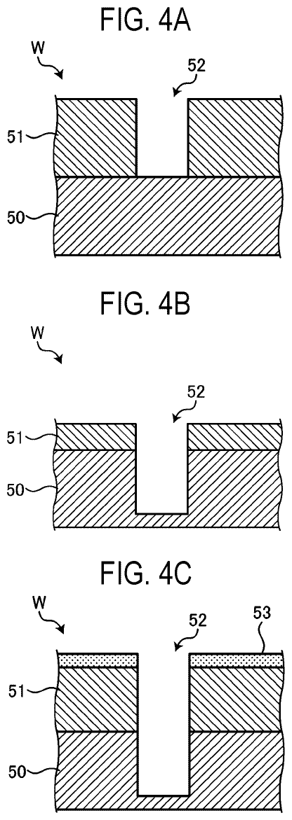

For the substrate W using the mask film having a ruthenium content of 100%, a cross-section of the substrate W after etching was investigated. In the experiment, the substrate W was used in which a mask film 51 is stacked on a silicon-containing film 50 and a predetermined pattern 52 is formed on the mask film 51, as illustrated in FIG. 4A, for example. Under the processing conditions of the comparative example in which CH₄ gas is not included in the process gas, for example, when the silicon-containing film 50 was etched along the pattern 52 of the mask film 51, as illustrated in FIG. 4B, no film formation was particularly confirmed on the surface of the mask film 51.

Meanwhile, under the processing conditions of the present embodiment in which the process gas contains CH₄ gas, for example, as illustrated in FIG. 4C, when the silicon-containing film 50 was etched along the pattern 52 of the mask film 51, the formation of a protective film 53 different from the mask film 51 was confirmed on the surface of the mask film 51.

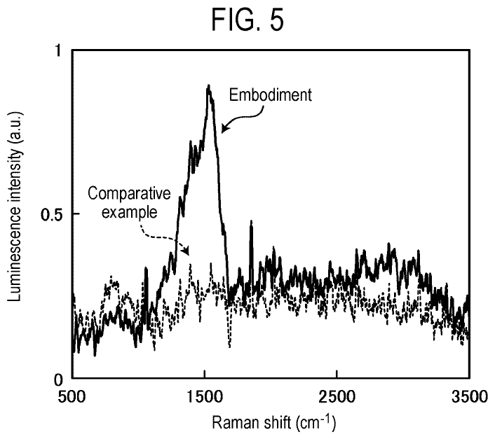

As a result of analyzing the substrate W of the comparative example and the substrate W of the present embodiment by Raman spectroscopy, a distribution in luminescence intensity as illustrated in FIG. 5 was observed. FIG. 5 is a diagram illustrating an example of a Raman shift of the uppermost surface of a mask film. As exemplified in FIG. 5, under the processing conditions of the present embodiment, a peak corresponding to a sp3 bond of carbon was observed, which was not observed in the substrate W after etching under the processing conditions of the comparative example.

Under the processing conditions of the present embodiment, it is considered that a protective film including diamond-like carbon having a sp3 bond is formed on the surface of the mask film by a catalytic effect of ruthenium included in the mask film due to plasma generated from the process gas including CH₄ gas. It is also considered that the etching of the mask film is suppressed by the protective film formed on the surface of the mask film, and thus the etch rate of the mask film is reduced.

### [Relationship Between Processing Time and Etch Rate]

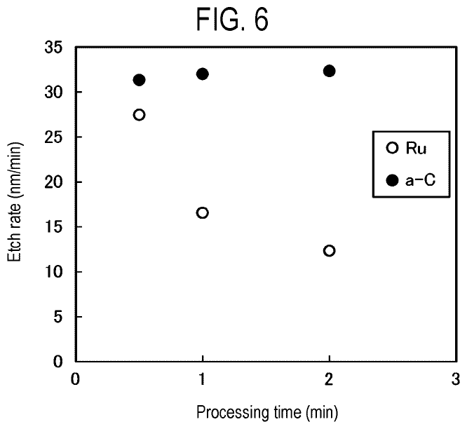

FIG. 6 is a diagram illustrating an example of a relationship between an etching processing time and an etch rate using a process gas including CF₄ gas and CH₄ gas for each of amorphous carbon and ruthenium. The other processing conditions in etching exemplified in FIG. 6 are the same as the processing conditions described above, which are the processing conditions of the present embodiment.

As shown in FIG. 6, for amorphous carbon, the etch rate hardly changes even as the processing time elapses. On the other hand, for ruthenium, the etch rate decreases as the processing time elapses. For ruthenium, it is considered that the etch rate decreases as the processing time elapses because a protective film including diamond-like carbon is formed on the surface of ruthenium as the processing time elapses.

### [Relationship Between Temperature of Substrate W and Etch Rate]

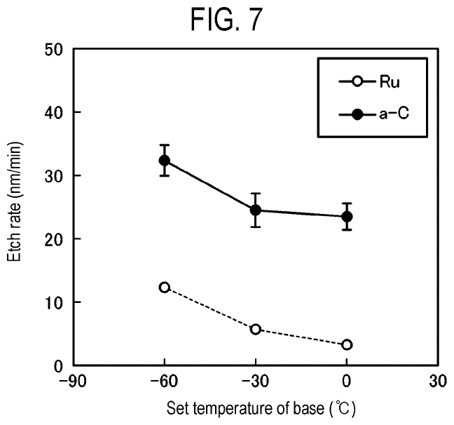

FIG. 7 is a diagram illustrating an example of a relationship between a set temperature of the base 1110 and an etch rate. In FIG. 7, temperature changes in etch rates of amorphous carbon and ruthenium are shown. In the experiment of FIG. 7, a process gas containing CF₄ gas and CH₄ gas was used. The processing conditions other than the temperature are the same as the processing conditions described above, which are the processing conditions of the present embodiment.

As shown in FIG. 7, at each of the temperatures of −60 degrees C., −30 degrees C., and 0 degrees C., the etch rate of ruthenium is lower than the etch rate of amorphous carbon. In addition, under the processing conditions of the present embodiment, the etch rate of ruthenium at 0 degrees C. was 3 nm/min, an etch rate of a silicon oxide film at 0 degrees C. was 430 nm/min, and an etch rate of a silicon nitride film at 0 degrees C. was 75 nm/min. In addition, under the processing conditions of the present embodiment, the etch rate of amorphous carbon at 0 degrees C. was 26 nm/min.

That is, under the processing conditions of the present embodiment, the ratio of the etch rate of the silicon oxide film to the etch rate of ruthenium at 0 degrees C. is 100 times or more. Furthermore, under the processing conditions of the present embodiment, the ratio of the etch rate of the silicon nitride film to the etch rate of ruthenium at 0 degrees C. is 20 times or more. Under the processing conditions of the present embodiment, sufficient selectivity is obtained by using the mask film containing ruthenium with respect to both the silicon oxide film and the silicon nitride film.

### [Addition Ratio of CH₄ Gas in Process Gas]

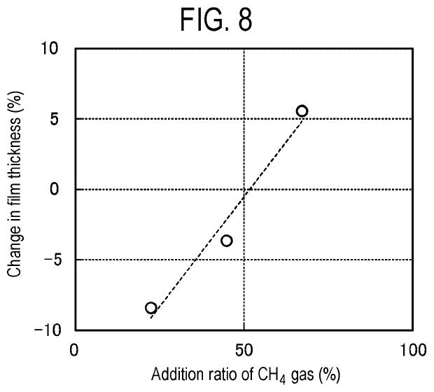

FIG. 8 is a diagram illustrating an example of a relationship between the addition ratio of CH₄ gas and a change in the thickness of a mask film. In FIG. 8, a change in film thickness when a mask film containing ruthenium is etched under the processing conditions of the present embodiment is illustrated. In the experiment of FIG. 8, the addition ratios of CH₄ gas in the process gas were 22.4%, 44.8%, and 67.2%. Under conditions in which the addition ratios of CH₄ gas in the process gas are low (22.4% and 44.8%), the film thickness decreases after an etching process as illustrated in FIG. 8, and etching of the mask film occurs. In contrast, under conditions in which the addition ratio of CH₄ gas in the process gas is high (67.2%), the film thickness increases after the etching process as illustrated in FIG. 8 to switch to a film formation mode.

Here, if the experimental results of FIG. 8 are linearly approximated, it can be seen that switching to the film formation mode occurs in a range in which the addition ratio of CH₄ gas is greater than about 50%. Therefore, in the etching process, it is desirable that the addition ratio of CH₄ gas be 50% or less.

Hereinabove, the embodiments have been described. As described above, the etching method in the present embodiment includes Process a), Process b), and Process c). In Process a), the substrate W including a mask film containing ruthenium and having a predetermined pattern formed in the mask film, and a silicon-containing film provided under the mask film is prepared in the plasma processing chamber 10. In Process b), a process gas including a hydrocarbon-containing gas and a fluorine-containing gas is supplied into the plasma processing chamber 10. In process C), the silicon-containing film is etched through the mask film using plasma generated from the process gas supplied into the plasma processing chamber 10. According to the etching method of the present embodiment, in etching, the selectivity of the mask film with respect to an etching target film can be improved.

In the above embodiment, the content of ruthenium in the mask film is 20% or more. As a result, the etching resistance of the mask film can be improved compared to the mask of amorphous carbon.

In the above embodiment, the hydrocarbon gas is, for example, CH₄ gas, and the flow rate ratio of the hydrocarbon gas to the process gas is 50% or less. As a result, the selectivity of the mask film containing ruthenium can be improved.

In the above embodiment, the silicon-containing film is a silicon oxide film, and in Process c), the ratio of an etch rate of the silicon-containing film to an etch rate of the mask film is 100 times or more. According to the etching method of the present embodiment, the silicon oxide film can be etched using the mask film having high selectivity.

In the above embodiment, the silicon-containing film is a silicon nitride film, and in Process c), the ratio of the etch rate of the silicon-containing film to the etch rate of the mask film is 20 times or more. According to the etching method of the present embodiment, the silicon nitride film can be etched using the mask film having high selectivity.

In the above embodiment, the silicon-containing film is a multilayer film of the silicon oxide film and the silicon nitride film. According to the etching method of the present embodiment, the multilayer film of the silicon oxide film and the silicon nitride film can be etched using the mask film having high selectivity.

In addition, the etching apparatus in the above embodiment includes the plasma processing chamber 10, the substrate support 11, the RF power supply 31, and the controller 2. The plasma processing chamber 10 has the gas supply port 13a and the gas discharge port 10e. The substrate support 11 is provided inside the plasma processing chamber 10 and supports the substrate W. The RF power supply 31 generates plasma from a process gas supplied into the plasma processing chamber 10. The substrate W includes a mask film containing ruthenium and having a predetermined pattern formed in the mask film, and a silicon-containing film provided under the mask film. The controller 2 executes Process a), Process b), and Process c). In Process a), the substrate W is prepared in the plasma processing chamber 10. In Process b), a process gas including a hydrocarbon-containing gas and a fluorine-containing gas is supplied into the plasma processing chamber 10. In process C), the silicon-containing film is etched through the mask film using plasma generated from the process gas supplied into the plasma processing chamber 10. According to the etching method of the present embodiment, in etching, the selectivity of the mask film with respect to an etching target film can be improved.

### [Others]

The technique disclosed in the present disclosure is not limited to the above-described embodiments, various modifications are possible within the scope of the present disclosure.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

The following supplementary notes are disclosed below with respect to the above embodiments.

### Supplementary Note 1

An etching method, including:
a) preparing, within a chamber, a substrate including a mask film containing ruthenium and having a predetermined pattern formed in the mask film, and a silicon-containing film provided under the mask film;
b) supplying a process gas including a hydrocarbon-containing gas and a fluorine-containing gas into the chamber; and
c) etching the silicon-containing film through the mask film using plasma generated from the process gas supplied into the chamber.

### Supplementary Note 2

The etching method of Supplementary Note 1, wherein a content of the ruthenium in the mask film is 20% or more.

### Supplementary Note 3

The etching method of Supplementary Note 1 or 2, wherein the hydrocarbon-containing gas is CH₄ gas.

### Supplementary Note 4

The etching method of any one of Supplementary Notes 1 to 3, wherein a flow rate ratio of the hydrocarbon-containing gas to the process gas is 50% or less.

### Supplementary Note 5

The etching method of any one of Supplementary Notes 1 to 4, wherein the silicon-containing film is a silicon oxide film.

### Supplementary Note 6

The etching method of Supplementary Note 5, wherein, in c), a ratio of an etch rate of the silicon-containing film to an etch rate of the mask film is 100 times or more.

### Supplementary Note 7

The etching method of any one of Supplementary Notes 1 to 4, wherein the silicon-containing film is a silicon nitride film.

### Supplementary Note 8

The etching method of Supplementary Note 7, wherein, in c), a ratio of an etch rate of the silicon-containing film to an etch rate of the mask film is 20 times or more.

### Supplementary Note 9

The etching method of any one of Supplementary Notes 1 to 4, wherein the silicon-containing film is a multilayer film of a silicon oxide film and a silicon nitride film.

### Supplementary Note 10

An etching apparatus, including:
a chamber having a gas supply port and a gas discharge port;
a substrate support portion provided inside the chamber to support a substrate;
a plasma generator configured to generate plasma from a process gas supplied into the chamber; and
a controller,
wherein the substrate includes a mask film including ruthenium and having a predetermined pattern formed in the mask film, and a silicon-containing film provided under the mask film, and
wherein the controller is configured to execute
a) preparing the substrate within the chamber,
b) supplying a process gas including a hydrocarbon-containing gas and a fluorine-containing gas into the chamber, and
c) etching the silicon-containing film through the mask film using plasma generated from the process gas supplied into the chamber.

According to various aspects and embodiments of the present disclosure, it is possible to improve the selectivity of a mask film with respect to an etching target film.

What is claimed is:

1. An etching method, comprising:
a) preparing, within a chamber, a substrate including a mask film containing ruthenium and having a predetermined pattern formed in the mask film, and a silicon-containing film provided under the mask film;
b) supplying a process gas including a hydrocarbon-containing gas and a fluorine-containing gas into the chamber; and
c) etching the silicon-containing film through the mask film using plasma generated from the process gas supplied into the chamber.

2. The etching method of claim 1, wherein a content of the ruthenium in the mask film is 20% or more.

3. The etching method of claim 1, wherein the hydrocarbon-containing gas is CH₄ gas.

4. The etching method of claim 2, wherein the hydrocarbon-containing gas is CH₄ gas.

5. The etching method of claim 1, wherein a flow rate ratio of the hydrocarbon-containing gas to the process gas is 50% or less.

6. The etching method of claim 1, wherein the silicon-containing film is a silicon oxide film.

7. The etching method of claim 6, wherein, in c), a ratio of an etch rate of the silicon-containing film to an etch rate of the mask film is 100 times or more.

8. The etching method of claim 1, wherein the silicon-containing film is a silicon nitride film.

9. The etching method of claim 8, wherein, in c), a ratio of an etch rate of the silicon-containing film to an etch rate of the mask film is 20 times or more.

10. The etching method of claim 1, wherein the silicon-containing film is a multilayer film of a silicon oxide film and a silicon nitride film.

11. An etching apparatus, comprising:
a chamber having a gas supply port and a gas discharge port;
a substrate support portion provided inside the chamber to support a substrate;
a plasma generator configured to generate plasma from a process gas supplied into the chamber; and
a controller,
wherein the substrate includes a mask film including ruthenium and having a predetermined pattern formed in the mask film, and a silicon-containing film provided under the mask film, and
wherein the controller is configured to execute
a) preparing the substrate within the chamber,
b) supplying a process gas including a hydrocarbon-containing gas and a fluorine-containing gas into the chamber, and
c) etching the silicon-containing film through the mask film using plasma generated from the process gas supplied into the chamber.
